(19) United States
(12) Patent Application Publication
(10) Pub. No.: US 2005/0269419 A1
(43) Pub. Date: Dec. 8, 2005

(54) Temperature control system

(76) Inventors: David D. Neranjan, Miramar, FL (US); Lenio H. Cacula, Miami Lakes, FL (US); Joao Carlos Chies, Miami Lakes, FL (US)

Correspondence Address: FROMMER LAWRENCE & HAUG, 745 FIFTH AVENUE- 10TH FL., NEW YORK, NY, 10151, US

(21) Appl. No.: 10/858,618

(22) Filed: Jun. 2, 2004

(51) Int. Cl. G05D 23/00; H03B 5/30; H03B 5/36; F25B 49/00

(52) U.S. Cl. 236/51; 62/126

(57) ABSTRACT

System for controlling temperature inside a structure. The system may comprise a remote control unit and a base unit couplable to one or more temperature adjusting devices. The base unit may include a receiver for receiving signals transmitted wirelessly, a short circuit protection circuit having a detection circuit for detecting a short in a temperature adjusting device and a terminating circuit for terminating control of the temperature adjusting device when a short is detected, a fuse circuit which causes a power supply circuit to stop supplying power to circuits within the base unit when a temperature therein is equal to a predetermined value, a control circuit, a display device, and first and second shift registers, wherein the display device is controlled by signals provided by the first and second shift registers. The remote control unit may include a transmitter for transmitting signals in a wireless manner.

### FIELD OF THE INVENTION

The present invention is directed to a temperature control system to control heating and/or cooling of a structure such as automobiles, boats, recreational vehicles, residential buildings, commercial buildings, and so forth. More specifically, the present invention is directed to a temperature control system that may control a number of temperature adjusting devices such as a fan, an air conditioner, a heat pump, and/or furnace.

### BACKGROUND OF THE INVENTION

Temperature control systems are used to control the temperature of a variety of structures. In such systems, an operator may set a temperature and/or a mode of operation. Such mode of operation may be a cooling mode or a heating mode. Based on the set temperature and mode, the system exercises control over a number of temperature adjusting devices to control the temperature of a structure.

In such temperature control systems, the operator may input temperature and/or mode information by use of an input panel located on a base unit and/or by use of a wireless remote unit. The present invention provides improvements to these temperature control systems.

### SUMMARY OF THE INVENTION

In accordance with an aspect of the present invention, a control system for controlling temperature inside a structure is provided. The system may comprise a base unit couplable to one or more temperature adjusting devices for controlling the same. The base unit may include a receiver for receiving control signals indicative of an input provided by an operator transmitted in a wireless manner, and a short circuit protection circuit having a detection circuit for detecting a short in a respective temperature adjusting device and a terminating circuit for terminating control of the respective temperature adjusting device when a short is detected therein. The system may further include a remote control unit having a transmitter for transmitting the operator control signals in a wireless manner for receipt by the receiver of the base unit.

In accordance with another aspect of the present invention, a control system for controlling temperature inside a structure is provided. The system may comprise a base unit having a plurality of circuits including a receiving circuit for receiving control signals indicative of an input provided by an operator transmitted in a wireless manner, a power supply circuit for supplying power to the circuits within the base unit, and a fuse circuit which causes the power supply circuit to stop supplying power to the circuits within the base unit when a temperature therein is equal to a predetermined value. The system may further comprise a remote control unit having a transmitter for transmitting the operator control signals in a wireless manner for receipt by the receiving circuit of the base unit.

In accordance with another aspect of the present invention, a control system for controlling temperature inside a structure is provided. The system may comprise a base unit having a plurality of circuits including a receiving circuit for receiving control signals indicative of an input provided by an operator transmitted in a wireless manner, a control circuit for controlling operations of the base unit, a display device, and first and second shift registers each coupled to the control circuit and the display device. The system may further include a remote control unit having a transmitter for transmitting the operator control signals in a wireless manner for receipt by the receiving circuit of the base unit. The display device is controlled by signals provided by the first and second shift registers.

In accordance with another aspect of the present invention, a control system for controlling temperature inside a structure is provided. The system may comprise a base unit couplable to an air conditioning device and a heating device for controlling the same. The base unit may include a receiving circuit for receiving control signals indicative of a set temperature supplied by an operator by way of an input device provided on the base unit or by way of control signals transmitted in a wireless manner, and a control circuit for controlling operations of the base unit. The system may further comprise a remote control unit having a transmitter for transmitting the operator control signals in a wireless manner for receipt by the receiving circuit of the base unit. The control circuit may add a first predetermined number to the set temperature to obtain a first temperature and subtract a second predetermined number from the set temperature to obtain a second temperature. The base unit may activate the air conditioning device when the temperature inside the structure is at or above the first temperature and may activate the heating device when the temperature inside the structure is at or below the second temperature.

### BRIEF DESCRIPTION OF THE DRAWINGS

The following Detailed Description, given to describe the invention by way of example, but not intended to limit the invention to specific embodiments described, may be understood in conjunction with the accompanying Figures, incorporated herein by reference, in which:

FIG. 1 is a diagram of a base unit and a number of remote controls according to an embodiment of the invention;

FIG. 2 is a schematic of the base unit according to an embodiment of the invention.

FIG. 3 is a schematic of the short circuit protection circuit according to an embodiment of the invention; and

FIG. 4 is a schematic of the LCD display circuit according to an embodiment of the invention.

### DETAILED DESCRIPTION OF THE INVENTION

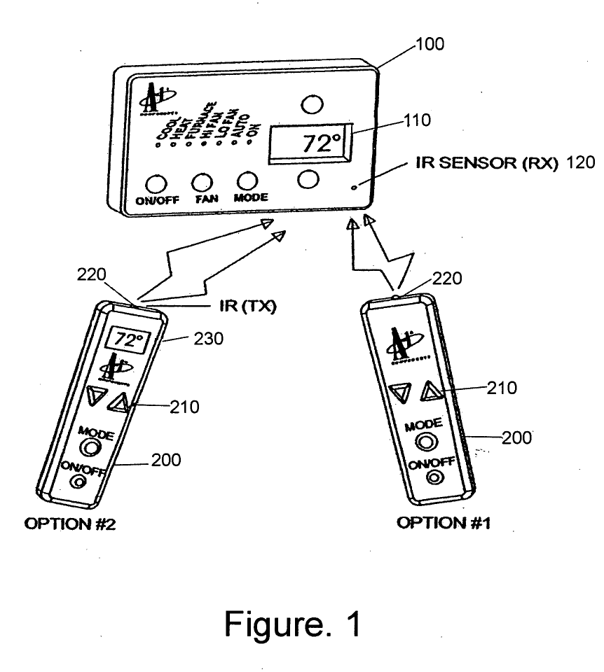

As shown in FIG. 1, a system in accordance with an embodiment of the invention may include a base unit 100. Base unit 100 may include a display unit 110 for displaying a temperature such as a 2½ digit seven segment liquid crystal display (LCD) and an (IR) infrared receiver 120. The system may also include a remote control 200 for wirelessly transmitting control signals to base unit 100. Remote control 200 may include control buttons 210 for increasing or decreasing a desired temperature, an IR transmitter 220 for transmitting a control signal to base unit 100, and a display 230 for displaying, among other things, the current temperature, desired temperature, and/or mode of operation.

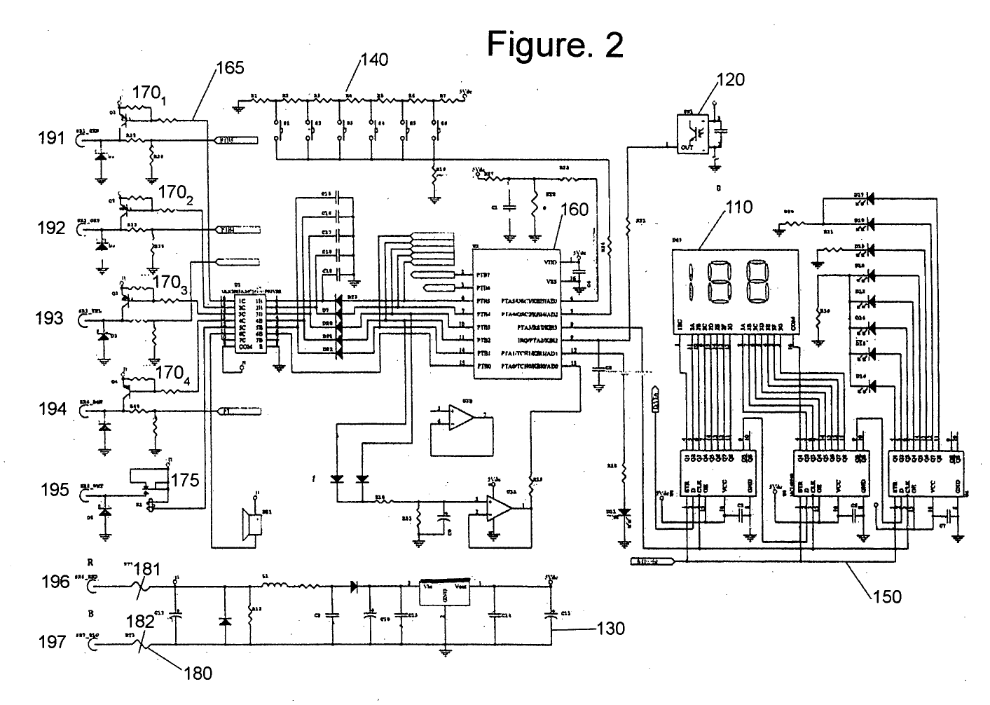

FIG. 2 depicts a schematic of the base unit 100 in accordance with an embodiment of the invention. Base unit 100 may include a processor 160 for receiving, processing, and outputting signals. An operator may input control signals to processor 160 via an input section 140. Input section 140 may be a number of toggle switches, a number of push button switches, or the like. Alternatively, an operator may utilize remote control 200 to transmit control signals via the IR transmitter 220 to an IR receiver 120 of base unit 100. Based on the received control signals, processor 160 may output control signals to various circuits in base unit 100.

Base unit 100 may be powered by a power supply 130. Power supply 130 may include a fuse circuit 180. Fuse circuit 180 may include one or more resetable fuses 181 and 182. Each resetable fuse may be utilized to protect the base unit 100 from a short circuit that may occur externally to base unit 100. That is, if a short circuit develops external to base unit 100, the flow of current from either inputs 196 or 197 will be theoretically infinite. The increased current may cause fuse circuit 180 to overheat. When such fuse circuit 180 reaches a predetermined temperature, the fuses open thereby stopping the supply of power to a number of circuits in base unit 100 such as relay circuit 175 which may control a temperature adjusting device coupled to output 195 such as a furnace.

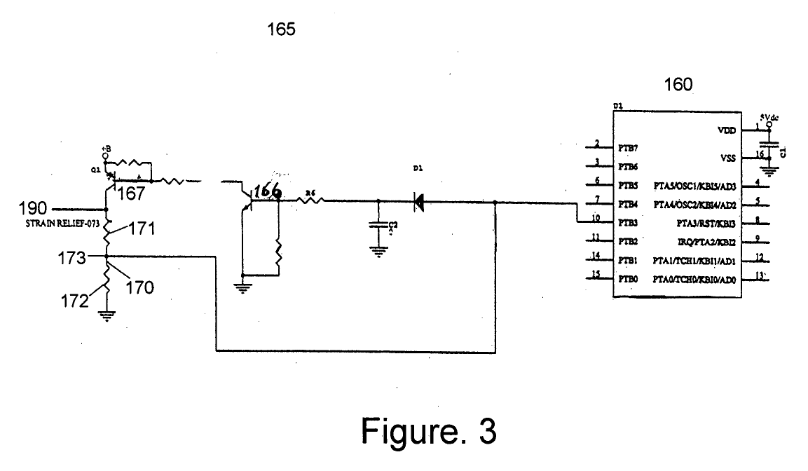

Processor 160 may output control signals to a number of temperature adjusting devices coupled to output terminals 191-195. Such temperature adjusting devices may include a high speed fan, a low speed fan, an air conditioner, and heat pump. Control signals from the processor 160 are sent to the temperature adjusting devices 191-194 via short circuit protection circuit 165 that will be described in detail below with regard to FIG. 3.

FIG. 3 is a diagram representative of a short circuit protection circuit 165. As shown in FIG. 3, when the processor 160 sends a control signal to control a temperature adjusting device, pin 10 of processor 160 outputs a logic high to the base of NPN transistor 166 to drive PNP transistor 167. As a result, the base of PNP transistor 167 of the short circuit protection circuit 165 may be driven so that a high voltage is provided at the collector of PNP transistor 167 while providing a high voltage at the output terminal 190. A high voltage at output terminal 190 controls a temperature adjusting device coupled to output terminal 190. After a predetermined time period, pin 10 may switch from an output pin to an input pin. Such predetermined time period may be set by software codes.

The short circuit protection circuit 165 may include a short circuit detector 170. Short circuit detector 170 may include at least two resistors 171 and 172 in a voltage divider configuration. When a short circuit occurs in a temperature adjusting device, a zero voltage is provided at output terminal 190 causing a zero voltage to be outputted from voltage divider at node 173. The zero voltage may be provided to pin 10 of processor 160 during a time when pin is set as an input pin. When a zero voltage is provided at pin 10, the processor terminates control of the temperature adjusting device coupled to output terminal 190 and causes such temperature adjusting device to terminate. After a short circuit has been detected, the temperature adjusting device may be monitored to determine if a short circuit still exists once every predetermined time period. Although the predetermined time period may preferably be approximately 30 seconds, it may be possible to set the predetermined time period to any duration using software codes.

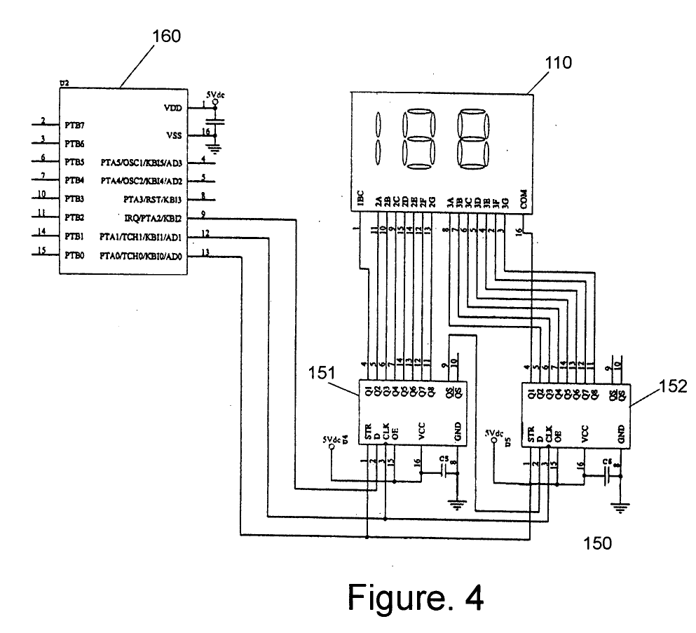

FIG. 4 is a diagram representing the display circuit 150. Display circuit 150 includes two shift registers 151 and 152. The shift registers receive three input signals from pins 9, 12, and 13 of processor 160. The three input signals received from the processor 160 are a data signal, a clock signal, and a strobe signal. Using these three signals, an unlimited number of segments may be driven without the need for more input/outputs from the processor 160 or a display driver. The data and clock signals carry information regarding a character to be displayed in a serial communication format. The strobe signal is responsible for eliminating any transient segments of the display.

In the auto changeover mode or method, an operator is able to select a desired temperature. After which a first predetermined number is added to the desired temperature resulting in a first temperature and a second predetermined number is subtracted from the desired temperature resulting in a second predetermined temperature. The first and second predetermined numbers may be set by the manufacturer, a retailer, and/or operator of the temperature control system. If the temperature of the structure is at or above the first temperature, base unit 100 may activate an air conditioning device. If the temperature of the structure is at or below the second temperature, base unit 100 may activate a heating device. If the temperature of the structure is between the first and second temperature, which is also known as a dead band, neither the air conditioning device nor the heating device area activated. An example of the auto changeover method will be described herein. It is important to note that although the example uses specific values, the present invention is by no means restricted to such values. In such method, if an operator sets a desired temperature to 75° F., and the temperature rises to 76° F., the air conditioner will be activated to bring the temperature to 74° F. The cycle will be repeated to maintain a 2° F. differential. On the other hand, if the temperature drops to 71° F., the heater will activate to raise the temperature to 73° F. in order to maintain the 2° F. differential. In the above example, a dead band of 1° F. exists between 73° F. and 74° F. where neither the air conditioning device nor the heating device would be activated.

The present invention provides a temperature control system for controlling a number of temperature adjusting devices such as a heating device and an air conditioning device, and which can be controlled by way of a base unit or by way of a remote control unit. The remote control unit may transmit signals in an infrared manner.

The remote control unit of the present invention has the ability to adjust set points from 30 feet away from the base unit.

The base unit of the present invention may incorporate short circuit protection for the outside temperature adjusting devices and shift registers as a display driver.

Having thus described in detail embodiments of the invention, it is to be understood that the invention defined by the appended claims is not to be limited to particular details set forth in the above description. Many apparent variations thereof are possible without departing from the spirit or scope of the invention.

1. A control system for controlling temperature inside a structure, said system comprising:
a base unit couplable to one or more temperature adjusting devices for controlling the same, said base unit including a receiver for receiving control signals indicative of an input provided by an operator transmitted in a wireless manner, and a short circuit protection circuit having a detection circuit for detecting a short in a respective temperature adjusting device and a terminating circuit for terminating control of said respective temperature adjusting device when a short is detected therein; and
a remote control unit having a transmitter for transmitting the operator control signals in a wireless manner for receipt by said receiver of said base unit.

2. The control system according to claim 1, wherein one or more of said one or more temperature adjusting devices include a fan, an air conditioner device, and a heat pump device.

3. The control system according to claim 1, wherein said terminating circuit terminates control of said respective temperature adjusting device and causes said respective temperature adjusting device to terminate when a short is detected therein.

4. The control system according to claim 3, wherein after the short is detected in said respective temperature adjusting device, said detection circuit monitors said respective temperature adjusting device to determine if the short still exists.

5. The control system according to claim 4, wherein after the short is detected in said respective temperature adjusting device, said detection circuit monitors said respective temperature adjusting device once in a predetermined time interval to determine if the short still exists.

6. The control system according to claim 5, wherein said predetermined time interval is approximately 30 seconds.

7. The control system according to claim 4, wherein if while monitoring said respective temperature adjusting device said detection circuit determines that the short no longer exists, then said terminating circuit causes said respective temperature adjusting device to be turned on and restores control of said respective temperature adjusting device.

8. The control system according to claim 1, wherein said transmitter of said remote control unit includes an infrared transmitting device and said receiver of said base unit includes an infrared receiving device, and wherein said infrared transmitting device transmits the control signals in an infrared manner.

9. A control system for controlling temperature inside a structure, said system comprising:
a base unit having a plurality of circuits including a receiving circuit for receiving control signals indicative of an input provided by an operator transmitted in a wireless manner, a power supply circuit for supplying power to the circuits within said base unit, and a fuse circuit which causes said power supply circuit to stop supplying power to the circuits within the base unit when a temperature therein is equal to a predetermined value; and
a remote control unit having a transmitter for transmitting the operator control signals in a wireless manner for receipt by said receiving circuit of said base unit.

10. The control system according to claim 9, wherein said fuse circuit includes one or more resetable fuse elements.

11. The control system according to claim 10, wherein the resetable fuse element or elements are operable to open when the temperature thereof is equal to said predetermined value.

12. A control system for controlling temperature inside a structure, said system comprising:
a base unit having a plurality of circuits including a receiving circuit for receiving control signals indicative of an input provided by an operator transmitted in a wireless manner, a control circuit for controlling operations of said base unit, a display device, and first and second shift registers each coupled to said control circuit and said display device; and
a remote control unit having a transmitter for transmitting the operator control signals in a wireless manner for receipt by said receiving circuit of said base unit,
wherein said display device is controlled by signals provided by said first and second shift registers.

13. The control system according to claim 12, wherein said display device includes a 2½ digit display.

14. A control system for controlling temperature inside a structure, said system comprising:
a base unit couplable to an air conditioning device and a heating device for controlling the same, said base unit including a receiving circuit for receiving control signals indicative of a set temperature supplied by an operator by way of an input device provided on said base unit or by way of control signals transmitted in a wireless manner, and a control circuit for controlling operations of said base unit; and
a remote control unit having a transmitter for transmitting the operator control signals in a wireless manner for receipt by said receiving circuit of said base unit,
wherein said control circuit adds a first predetermined number to said set temperature to obtain a first temperature and subtracts a second predetermined number from said set temperature to obtain a second temperature, and wherein said base unit activates said air conditioning device when the temperature inside said structure is at or above said first temperature and activates said heating device when the temperature inside said structure is at or below said second temperature.
